(19) United States
(12) Patent Application Publication
(10) Pub. No.: US 2005/0016453 A1
(43) Pub. Date: Jan. 27, 2005

(54) Collection of unused precursors in ALD

(76) Inventors: Thomas E. Seidel, Sunnyvale, CA (US); Edward C. Lee, Cupertino, CA (US); Kenneth Doering, San Jose, CA (US); Prasad Gadgil, Santa Clara, CA (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/831,456

(22) Filed: Apr. 23, 2004

Related U.S. Application Data
(60) Provisional application No. 60/465,142, filed on Apr. 23, 2003.

(51) Int. Cl. C23C 16/00

(52) U.S. Cl. 118/715

(57) ABSTRACT

An ALD system includes an ALD reactor and a precursor trap coupled downstream of the ALD reactor via a valve assembly. The precursor trap is configured to collect unused chemical precursors after reactions in the ALD reactor.

### RELATED APPLICATIONS

The present application is related to, incorporates by reference and hereby claims the priority benefit of U.S. Provisional Application 60/465,142, filed Apr. 23, 2003.

### FIELD OF THE INVENTION

The present invention relates to apparatus and methods for the collection and recovery of unused atomic layer deposition (ALD) precursors.

### BACKGROUND

There are many descriptions of ALD processes, wherein various chemistries and both thermal and plasma assisted ALD approaches are used. See, e.g., T. Suntola, “Atomic Layer Epitaxy”, Material Science Reports, v. 4, no. 7, p. 266 (1989); J. Klaus, et al., “Atomic layer deposition of tungsten using sequential surface chemistry with a sacrificial stripping reaction”, Thin Solid Films, v. 360, p. 145 (2000); S. Imai, “Hydrogen Assisted ALE of Silicon,” Appl. Surf. Sci. v.82-83, pp. 322-6 (1994); S. M. George, Applied Surf. Sci., v. 82/82 pp. 460-67 (1994); and M. A. Tischler & S. M. Bedair, “Self-limiting mechanism in the atomic layer epitaxy of GaAs”, Appl. Phys. Lett., 48(24), 1681 (1986). ALD technology uses sequential chemisorbed self-limiting and self-passivating “tmonolayer” reactions on a heated surface to grow various layers on that surface.

During ALD processes, reactive precursors are alternately pulsed onto the heated surface, each precursor application being separated by an inert purge gas half-cycle. Each self-limiting chemical half-reaction (e.g., for metal and non-metal reactions) follows exponential or Langmuir kinetics, allowing for the monolayer growth. An initiation process is key to a continuous startup of a next monolayer growth process in the sequence, e.g., surface preparation to achieve: Si—OH. Applications of ALD to various situations, such as the deposition of higher K dielectrics (higher K than SiO₂) for advanced DRAM capacitors, are known. See, e.g., M. Gutsche et al., “Capacitance Enhancements techniques for sub 100 nm trench DRAMs”, IEDM, 411 (2001).

There are also a number of descriptions of ALD reactor architectures in the patent literature. See, e.g., U.S. Pat. Nos. 4,389,973; 5,281,274; 5,855,675; 5,879,459; 6,042,652; 6,174,377 6,387,185 and 6,503,330. Both single wafer and batch reactors are used, and plasma capabilities accompany some embodiments. In Suntola's seminal patent (4,389,973), the diffusive nature of the pulsed chemical precursors is described. The broadening of the pulse by gaseous diffusion places a fundamental limit on how short the interval between pulses can be. More diffusive conditions mean longer purge intervals to maintain a desired precursor pulse separation during the ALD cycle to achieve near-ideal ALD.

Briefly, ALD is carried out using self-saturating reactions where the ALD deposition rate (average deposition rate of A/cycle) is observed to increase as a function of exposure dosage (or time for a given precursor flux). Conventional ALD operation allows for and encourages “over-dosage” so that the exposure time for a given dose is more than enough at least for all regions of the substrate. This conventional wisdom has been the practice of record for ALD technology since 1977 and is highly referenced, for example in review articles by M. Ritala & M. Leskela, “Deposition and Processing”, in Handbook of Thin Film Materials (H. S. Nalwa ed.), v.1, ch.2 (2002) and O. Sneh, et. al., “Equipment for Atomic Layer Deposition and Applications for Semiconductor*Processing,” Thin Solid Films, v. 402/1-2, pp. 248-261, (2002). In this overdosed mode it is relatively easy to obtain saturation for all points on the substrate and gas dynamics and kinetics play only a minor role. Id.

An ALD growth rate of a few Angstroms/cycle with a cycle time of a few seconds for 50 Å films results in a throughput of approximately 15 wafers per hour for a single wafer reactor. Current technology uses rapid switching for exposure and purge, with computer controlled electrically driven pneumatic valves providing precursors pulsed with precision of 10 s of milliseconds. It is also recommended that reactor volume be “small” to facilitate precursor purging and use of heated walls to avoid the undesired retention precursors such as water of ammonia through the ALD cycle. See, Ritala & Leskela, supra.

The current ALD practice of over-dosage is an inefficient process and has many limitations. For example, the chemical precursor dose in some regions of a substrate would necessarily continue to be applied even though the film has already reached saturation in that location, while reaching saturation in some other part of the reactor. The result is that this excess precursor is unused and wasted, adding cost for excess chemical usage. Additionally, the purge part of the ALD cycle is burdened with removing more than the necessary amount of precursor for global film coverage. Furthermore, the additional time used to globally cover the substrate while overdosing the first exposed regions will add to the diffusion broadening of the precursor pulses, further increasing the interval of purges to reach some useful minimal co-existence of concentrations of precursors in the gas phase. Some of the present inventors have proposed a scheme referred to as Transient Enhanced ALD (TE-ALD) to overcome the difficulties of inefficient exposure during ALD. See, e.g., U.S. patent application Ser. No. 10/791,334, filed Mar. 1, 2004, assigned to the assignee of the present invention and incorporated herein by reference.

In the interest of efficient ALD operation, then designing an ALD system that makes efficient use of precursor reactants is a priority. Today's overdose mode reactors are only about 5-20% efficient. That is, only about 5-20% of the metal in the incoming precursor is incorporated into the film. With TE-ALD, the amount of wasted precursor in minimized, and overall process may be on the order of 50% efficient. Still, there will always be some unused and wasted precursor, so in the case where the precursor is very expensive or consists of precious metal such as Pt, there will be a need to consider the recovery of the unused precursor reactant.

### SUMMARY OF THE INVENTION

An ALD system includes an ALD reactor and a precursor trap coupled downstream of the ALD reactor via a valve assembly. The precursor trap is configured to collect unused chemical precursors after reactions in the ALD reactor. In some embodiments, the valve assembly may include a pair of valves configured to be time-phase operated such that a first one of the pair of valves opens during periods of a first precursor exposure and its purge, during which time a second one of the pair of valves is closed, permitting unused portions of the first precursor to be directed to the precursor trap. The valves used for the valve assembly may be fast switching throttle valves. Where a compact ALD reactor is used, the valve assembly may be attached to effluent surfaces thereof.

Preferably, the valve assembly is actuated at a time later than initiation of a first precursor exposure time by a time interval substantially equal to a time for the first precursor to move between an upstream injecting valve and the downstream trap. Thus, in various embodiments the present invention includes a method for time phase operating a pair of valves coupled downstream from an ALD reactor such that a first one of the pair of valves opens during periods of exposure of a first precursor and its purge while at substantially the same time a second one of the pair of valve is closed, so as to selectively permit unused portions of the first precursor to be collected by a precursor trap downstream of the ALD reactor. Alternatively, or in addition, the present methods include actuating a valve coupled downstream of an ALD reactor and upstream of a precursor trap at a time later than initiation of a first precursor exposure time by a time interval substantially equal to a residence time of the first precursor and its purge in the ALD reactor.

The present invention is illustrated by way of example, and not limitation, in the figures of the accompanying drawings, in which:

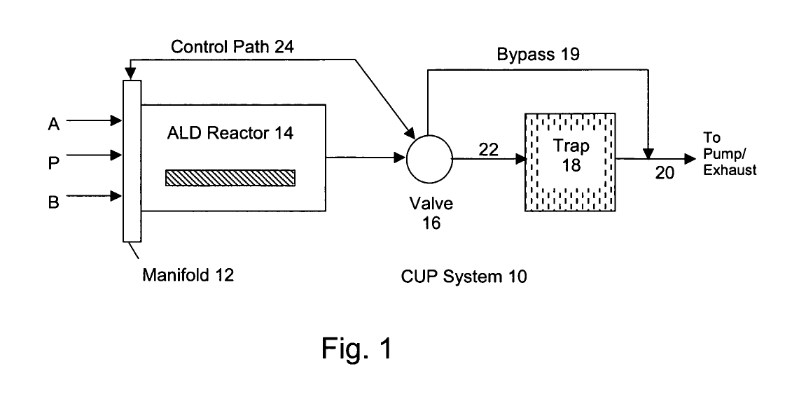

FIG. 1 illustrates an example of an ALD reactor system having a precursor trap configured in accordance with an embodiment of the present invention;

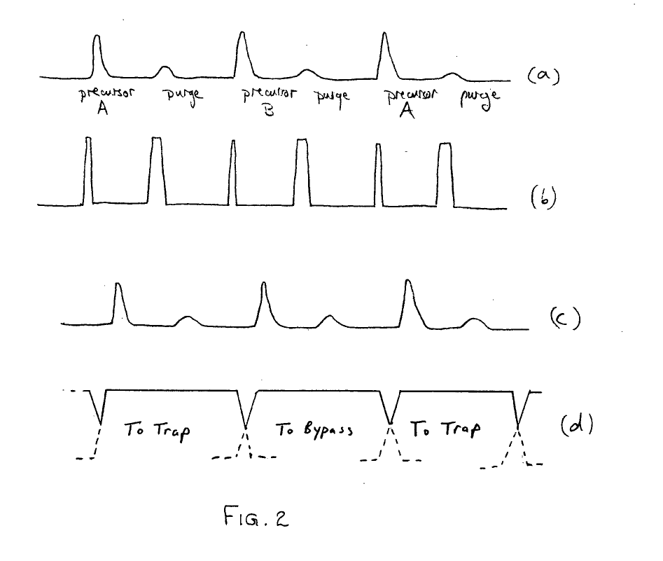

FIG. 2 illustrates examples of gas pressure variations and valve timings at selected points of the ALD system shown in FIG. 1.

### DETAILED DESCRIPTION

Described herein are apparatus and methods for the collection and recovery of unused precursors (CUP) in a downstream trap of an ALD reactor. These methods and apparatus will be discussed with reference to various illustrated embodiments, however, it should be remembered that these embodiments are presented merely as examples of the present methods and systems and should not be read as somehow limiting the scope of the present invention. The CUP technology described herein may be used in conjunction with conventional ALD processes and reactors, where (relatively speaking) a considerable amount of precursor is unused. Alternately, CUP may be used in combination with certain enhanced ALD equipment and processes, such as the TEALD process discussed above, where more efficient use of precursors is achieved.

ALD, in contrast to CVD (chemical vapor deposition), offers a special opportunity to collect nearly pure, unused precursors since ALD reactants are separately pulsed into the reactors and, hence, may be separately collected. Referring then to FIG. 1, an ALD reactor system (hereinafter referred to as a CUP reactor system) 10 configured in accordance with an embodiment of the present invention is illustrated. CUP reactor system 10 includes a gas manifold 12, which permits application of chemical precursors (e.g., precursors A and B) and/or a neutral purge gas P. Using this manifold 12, the reactive precursors and neutral purge and carrier gases are introduced into the ALD reactor 14. Gases are pumped from the ALD reactor 14 via a pump (not shown). During removal, the gases may be selectively diverted using a fast switching valve (or combination of valves or valve switching module or assembly) 16. In the case where the gases include desired (to be collected), unused precursors, the valve 16 is operated so as to divert the gases into a downstream precursor trap 18 (via conduit 22) having a coolant or other trapping mechanism to collect the unused precursor. This downstream trap 18 is, in turn, connected to the exhaust pump through conduit 20. Where the evacuated gases do not include desired (not to be collected), unused precursor, the valve 16 is operated so as to divert the gases via bypass conduit 19, directly to the exhaust conduit 20.

Thus, ALD system 10 includes an ALD reactor 14 and a downstream precursor trap 18. The precursor trap 18 is configured to collect unused chemical precursors after reactions in the ALD reactor 14. The fast switching valve 16 may be implemented as a pair of valves configured to be time-phase operated such that a first one of the pair of valves opens during periods of a first precursor exposure (e.g., precursor A) and its purge, during which time a second one of the pair of valves is closed, permitting unused portions of the first precursor (A) to be directed to the precursor trap 18. Preferably, the actuation speed (i.e., the time between application of an electrical actuation signal and the actual opening/closing of the valve) of the downstream switching valve 16 is less than the purge time period for the precursor being trapped. Such actuation speeds may allow for effective CUP operation. Recently, fast switching throttle valves have become commercially available with response times on the order of approximately 100 msec. These valves have a high conductance when in the open state, suitable to pass the unused precursors to the trap 18 and to pass the unused disposable precursors directly to the pump. Where a compact ALD reactor 14 (e.g., of the form discussed below) is used, the valve assembly may be attached to effluent surfaces thereof.

During operation, the chemical precursors may be pulsed in a conventional fashion or the ALD cycle may be relaxed to longer timings for better CUP realization. The fast-switching valve 16 (which may or may not be a pneumatic valve) is connected between the ALD reactor 14 and the precursor trap with a conduit 22. In the event that suitably large valve having a suitable conductance for downstream switching for this application are unavailable for even higher speed operation, one may employ a set of commonly available switching valves (for example of the pneumatic design with switching times down to 10 msec) and place them in parallel to provide the necessary conductance. Alternately, a large conductance bellows constructed (or “make/break”) valve may be used.

It is possible that the downstream, unused precursors will broaden by gaseous diffusion on their way to the exhaust pump. For CUP operation, if the chemical precursors are diffusion broadened they are more difficult to collect in pure form. To overcome this difficulty, embodiments of the present inventions may utilize a compact form of ALD reactor 14 designed for small footprint operation. This reactor is described in co-pending U.S. patent application Ser. No. 10/282,609, filed Oct. 29, 2002, assigned to the assignee of the present invention and incorporated herein by reference. This compact ALD reactor (known as a Massively Parallel Vertically Stacked ALD Reactor) is especially suitable for CUP implementation because of the short path to move unused precursors from the ALD reactor to the trap. In particular, the exhaust conduit is extremely short and may be directly connected to the fast switching valves, which, in turn, are connected directly to the trap.

The control path 24 in CUP reactor system 10 provides timing for manifold 12 and valve 16 to switch the gases to be trapped in the precursor trap 18 in time phase with the exiting of the unused precursor gas from ALD reactor 14. That is, the valve assembly 16 may be actuated at a time later than initiation of a first precursor exposure time by a time interval substantially equal to a time for the first precursor to move between an upstream injecting valve in manifold 12 and the downstream trap 18 (e.g., the entrance to valve assembly 16). Thus, in various embodiments the present invention provides for time phase operation of valve 16 (which, as indicated above, may be a pair of valves coupled downstream from ALD reactor 14) such that the path to trap 18 via conduit 22 is open during periods of exposure of a first precursor and its purge. Where a pair of valves is used, the valve leading to trap 18 would be open while at substantially the same time the second of the pair of valves (leading to bypass conduit 19) would be closed. In this way selective collection of unused portions of the first precursor by precursor trap 18 might be accomplished. When no precursor collection is desired, the valve leading to bypass conduit 19 is opened and the valve leading to conduit 22 is closed.

Referring to the timing diagram illustrated in FIG. 2, the uppermost trace (labeled (a)) is an illustration of pressure variations in the ALD reactor 14, due to the actuation of the signals applied to the upstream gas switching manifold 12, which actuation signals are shown in the second trace (labeled (b)). The relative heights of the pressure variations are not significant. The third trace (labeled (c)) is an illustration of the pressure variations downstream of the ALD reactor 14, for example in the exhaust conduit 20. These pressure variations are due to the passage of unused reactants and reaction byproducts and in general will be at a lower pressure with more diffusion broadening (not shown) than the uppermost trace (a). The actuation signals for the downstream switching valve or valves are shown in the fourth trace (labeled (d)). One of the valves (if a pair of valves is used, or one of the flow paths of a single valve) is open when the trap is used to collect unused precursors and the other valve (or flow path) is closed during this time. The time duration of this collection phase of operation is approximately equal to the period of the precursor pulse and its purge. Thereafter, the valve open/closed positions are reversed for bypass operation.

The upstream and downstream valve actuation signals (traces (b) and (d)) are shown as “rectangular shape” and are controlled to approximately 1 msec sharpness. The corresponding pressure change in the ALD reactor (shown in trace (a)) is delayed by a few tens of milliseconds, but the pressure trace indicates the effect of precursor diffusion broadening a short time following the precursor valve actuation. In CUP operation, the timing delay of the downstream fast switching valve 16 is adjusted to coincide to the time of passage of the unused precursor through to the reactor exhaust conduit. Hence, the valve assembly may be optimally actuated at a time that is shifted relative to the initiation of a first precursor exposure time, with a time shifted interval substantially equal to a time it takes for the first precursor to move between an upstream injecting valve and the downstream trap. This shift may also be referred to as the residence time for movement of the precursors through the system. This is illustrated by the time-shifted traces (c) and (d). Note that these traces are illustrative only and, in particular, trace (c) may be diffusion broadened more than trace (a). In such a manner the unused precursor may be passed to the trap 18. Valve 16 is operated so that one of the flow paths is (essentially) always open. That is, either the path to trap 18 or the bypass path via conduit 19 is always open to allow uninterrupted exhaust from the ALD reactor 14. In FIG. 2, trace (d) shows the falling edge of the first pulse to intersect the rising edge of the second pulse approximately at their midpoints. The pulses may be further overlapped, insuring uninterrupted exhaust, but extreme overlap would dump some desired precursor into the bypass and be lost from going into the trap.

There are a number of commercial trap designs available to implement the CUP reactor system described herein. In general, the trap may be “passive” or “active”. A passive trap is one wherein the unused chemical precursors may be trapped by low temperature or physically adsorbing surfaces. Alternately, an active trap is one wherein a surface catalytic process is used to react with the precursor, or a second chemical may be injected into the trap in a manner to react and precipitate out the desired elements of the unused precursor. Interestingly, many ALD processes are run with two highly reactive precursors, but in the ALD reactor they are not mixed in time and space. The two complementary reactants nevertheless react in CVD mode, so in the trap a time-phased injection of the complementary reactant may be used so that the trap becomes essentially a CVD reactor, with gas phase reactions taking place and forming precipitates that can be extracted.

Exchange byproducts generally accompany the unused precursor during ALD in the purge part of the cycle. Therefore it is unlikely that the unused precursor can be collected in a pure form and the byproducts collected separately, unless the trap is designed to do so. Stated differently, pure unused precursor can be collected separately of ALD byproducts if the trap is configured to so separate the precursor and the exchange byproducts. The reduction of hazardous effluents would have to be considered on a case-by-case reaction chemistry basis. CUP would seem to be most attractive for the use of ultra-high purity and expensive precursors and precious elements, such as Platinum.

Thus, apparatus and methods for the collection and recovery of unused precursors in a downstream trap of an ALD reactor have been described. Although discussed with reference to several illustrated embodiments, however, the scope of the present invention should be measured solely in terms of the claims, which now follow.

1. An ALD system, comprising an ALD reactor and a precursor trap coupled downstream of said ALD reactor via a valve assembly and configured to collect unused chemical precursors after reactions in said ALD reactor.

2. The ALD system of claim 1, wherein the valve assembly comprises a pair of valves configured to be time-phase operated such that a first one of the pair of valves opens during periods of a first precursor exposure and its purge, during which time a second one of the pair of valves is closed, permitting unused portions of the first precursor to be directed to the precursor trap.

3. The ALD system of claim 2 wherein the first and second ones of the pair of valves are fast switching throttle valves.

4. The ALD system of claim 1, wherein the valve assembly is attached to effluent surface of said ALD reactor.

5. The ALD system of claim 1, wherein the valve assembly is actuated at a time later than initiation of a first precursor exposure time by a time interval substantially equal to a time for the first precursor to move between an upstream injecting valve and the downstream trap.

6. A method, comprising time phase operating a pair of valves coupled downstream from an ALD reactor such that a first one of the pair of valves opens during periods of exposure of a first precursor and its purge while at substantially the same time a second one of the pair of valve is closed, so as to selectively permit unused portions of the first precursor to be collected by a precursor trap downstream of the ALD reactor.

7. A method, comprising actuating a valve coupled downstream of an ALD reactor and upstream of a precursor trap at a time later than initiation of a first precursor exposure time by a time interval substantially equal to a residence time of the first precursor and its purge in the ALD reactor.
